(19) United States
(12) Patent Application Publication
(10) Pub. No.: US 2026/0122777 A1
(43) Pub. Date: Apr. 30, 2026

(54) FLEXIBLE DIE-CUT CIRCUIT BOARD AND METHOD OF MANUFACTURING SAME

(71) Applicant: SK On Co., Ltd., Seoul (KR)

(72) Inventors: Dae Gyun HWANG, Daejeon (KR); Yun Joo NOH, Daejeon (KR); Hui Jun SHIN, Daejeon (KR); Hoe Wook CHOI, Daejeon (KR); Chong Pyo HONG, Daejeon (KR)

(21) Appl. No.: 19/370,768

(22) Filed: Oct. 28, 2025

(30) Foreign Application Priority Data
Oct. 29, 2024 (KR) 10-2024-0149430

(51) Int. Cl. H05K 1/02; H05K 3/04

(52) U.S. Cl. CPC H05K 1/0277; H05K 3/041; H05K 2201/10181; H05K 2203/1189

(57) ABSTRACT

Proposed are a flexible die-cut circuit board including a substrate made of a flexible material, the substrate having a first surface and a second surface opposite to the first surface, at least one trace formed on the first surface of the substrate, a pattern fuse formed as a portion of the trace, the pattern fuse having a smaller thickness than other portions of the trace and being configured to break when excessive current flows, and a protective layer configured to cover the trace and the pattern fuse, wherein the pattern fuse is formed in a pattern having a curved shape in a direction perpendicular to the first surface of the substrate, and a method of manufacturing the same.

### CROSS REFERENCE TO RELATED APPLICATION

The present application claims priority to Korean Patent Application No. 10-2024-0149430, filed Oct. 29, 2024, the entire contents of which is incorporated herein for all purposes by this reference.

### BACKGROUND

### 1. Technical Field

The embodiments of the present disclosure relate generally to an improved circuit board and a method of manufacturing the same.

### 2. Description of the Related Art

Circuit boards can connect various electronic components, including semiconductor chips, sensors, and connectors. Such circuit boards have been used in various electronic devices. Flexible circuit boards, made of flexible materials, can be used in electronic devices of various structures due to having flexibility. For example, a flexible circuit board can be used to connect a sensor and a connector in a battery module.

To protect various electronic components connected to a circuit board from excessive current, a fuse may be connected to the circuit board. Such a fuse may break when excessive current flows, thus blocking current flow. For example, a flexible circuit board used in a battery module may be connected to a fuse.

### SUMMARY

According to an embodiment of the present disclosure, there are provided a flexible die-cut circuit board including a pattern fuse formed with a thin trace thickness, and a method of manufacturing the same.

According to an embodiment of the present disclosure, there are provided a flexible die-cut circuit board including a pattern fuse in which a pattern curve is formed in the thickness direction, and a method of manufacturing the same.

A flexible die-cut circuit board and a method of manufacturing the same, according to an embodiment of the present disclosure, may be widely applied to the field of green technology, including electric vehicles, battery charging infrastructures, and other battery-based solar and wind power generation systems.

A flexible die-cut circuit board and a method of manufacturing the same, according to an embodiment of the present disclosure, may be used in eco-friendly electric vehicles, hybrid vehicles, and the like for preventing climate change by suppressing air pollution and greenhouse gas emissions.

According to an embodiment of the present disclosure, a flexible die-cut circuit board may include: a substrate made of a flexible material, the substrate having a first surface and a second surface opposite to the first surface; at least one trace formed on the first surface of the substrate; a pattern fuse formed as a portion of the trace, the pattern fuse having a smaller thickness than other portions of the trace and being configured to break when excessive current flows; and a protective layer configured to cover the trace and the pattern fuse.

According to an embodiment, the pattern fuse may be formed in a pattern having a curved shape in a direction perpendicular to the first surface of the substrate.

According to an embodiment, the trace and the pattern fuse may have the same width in at least one portion.

According to an embodiment, the pattern fuse may be formed in a pattern in which a convex portion and a concave portion are formed repeatedly in a direction perpendicular to the first surface of the substrate.

According to an embodiment, the convex portion and the concave portion of the pattern fuse may be positioned within a thickness of the trace.

According to an embodiment of the present disclosure, a method of manufacturing a flexible die-cut circuit board may include the following steps: pressing a metal film using press dies at a region where a pattern fuse is to be formed in the metal film; forming a trace and the pattern fuse by performing die-cutting on the metal film so that the pressed region of the metal film is included in the trace; and manufacturing a circuit board by aligning the trace and the pattern fuse on a first surface of a substrate made of a flexible material and then forming a protective layer configured to cover the trace and the pattern fuse on the substrate.

According to an embodiment, the pattern fuse may be formed in a pattern having a curved shape in a direction perpendicular to the first surface of the substrate.

According to an embodiment, the press dies may include: a lower die configured to support a lower surface of the metal film at the region where the pattern fuse is to be formed; and an upper die configured to press an upper surface of the metal film at the region where the pattern fuse is to be formed.

According to an embodiment, a first curved pattern having a convex shape on an upper surface of the lower die, the upper surface being in contact with the region where the pattern fuse is to be formed, may be formed in the lower die, and a second curved pattern having a convex shape on a lower surface of the upper die, the lower surface being in contact with the region where the pattern fuse is to be formed, so as to correspond to a concave portion of the first curved pattern may be formed in the upper die.

According to an embodiment, in the step of forming the trace and the pattern fuse, the die-cutting may be performed so that the trace and the pattern fuse have the same width in at least one portion.

According to an embodiment, the pattern fuse may be formed in a pattern in which a convex portion and a concave portion are formed repeatedly in a direction perpendicular to the first surface of the substrate.

According to an embodiment, the convex portion and the concave portion of the pattern fuse may be positioned within a thickness of the trace.

The features and advantages of the present disclosure will become more apparent from the following detailed description based on the accompanying drawings.

Before discussing the description, it should be noted that all terms or words used herein and used in the appended claims should not be construed as general and dictionary meanings, but should be interpreted based on the meanings and concepts corresponding to the technical ideas of the present disclosure, following the principle that any inventor is allowed to define the concepts of terms as appropriate to describe the disclosure thereof in the best mode.

According to an embodiment of the present disclosure, a trace in which a pattern fuse having a small thickness is formed can be manufactured.

According to an embodiment of the present disclosure, a pattern fuse can be formed on a flexible die-cut circuit board to replace a chip fuse.

### BRIEF DESCRIPTION OF THE DRAWINGS

FIG. 1 is a view illustrating a battery module to which a flexible die-cut circuit board according to an embodiment of the present disclosure is applied;

FIG. 2 is a view illustrating a flexible die-cut circuit board according to an embodiment of the present disclosure;

FIG. 3 is a cross-sectional view taken along the line A-A′ of FIG. 2;

FIG. 4 is a flowchart illustrating each step constituting a method of manufacturing a flexible die-cut circuit board according to an embodiment of the present disclosure; and

FIGS. 5, 6, and 7 are views illustrating each step constituting a method of manufacturing a flexible die-cut circuit board according to an embodiment of the present disclosure.

### DETAILED DESCRIPTION

Hereinafter, the embodiments of the present disclosure are to be described in detail (with reference to the accompanying drawings). However, this is only for illustrative purposes, and the embodiments may not be limited only to the specific embodiments illustrated below.

Hereinafter, the embodiments of the present disclosure will be described in detail with reference to the accompanying drawings.

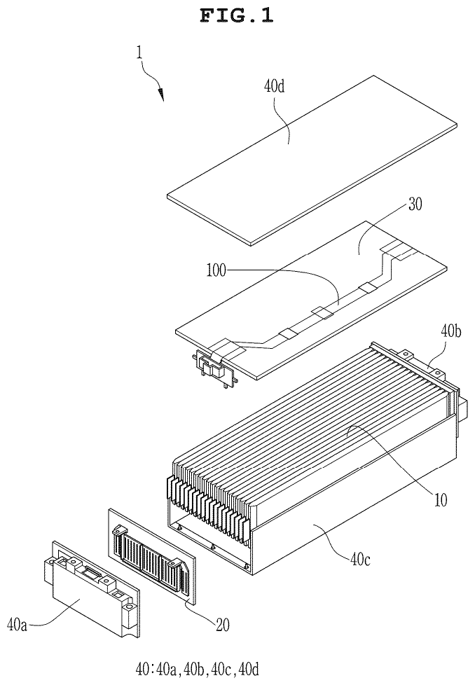

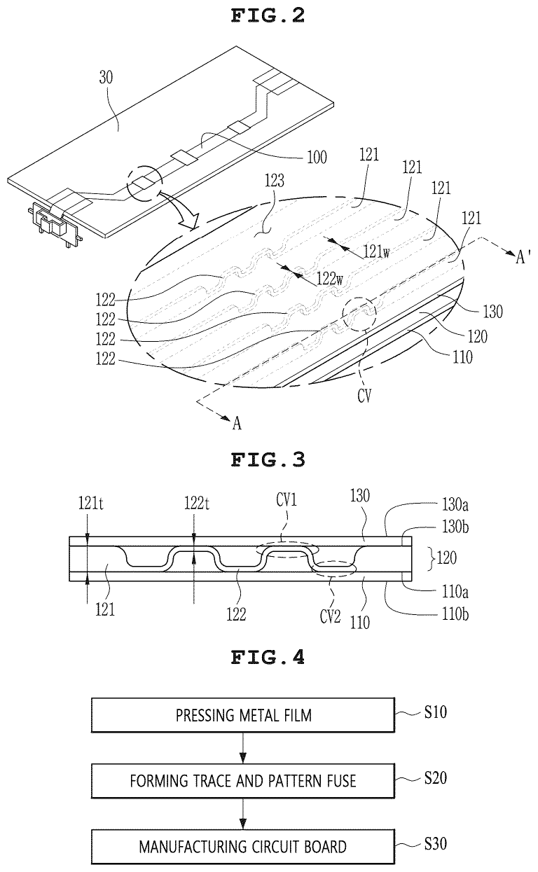

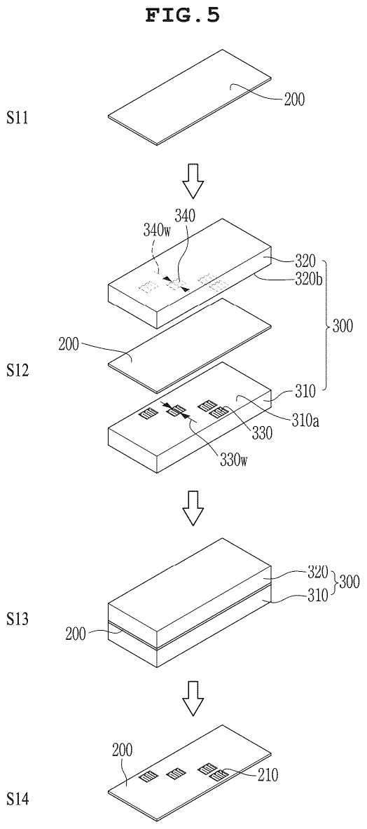

FIG. 1 is a view illustrating a battery module 1 to which a flexible die-cut circuit board 100 according to an embodiment of the present disclosure is applied. FIG. 2 is a view illustrating the flexible die-cut circuit board 100 according to an embodiment of the present disclosure. FIG. 3 is a cross-sectional view taken along the line A-A′ of FIG. 2.

The battery module 1 may be used for electric vehicles, energy storage systems (ESSs), and various other purposes. The battery module 1 may include: a plurality of battery cells 10; a busbar assembly 20 configured to deliver power from the battery cells 10 by connecting a plurality of tabs of the plurality of battery cells 10; a circuit board 30 configured to perform data transmission and reception or monitoring of the module status; and a case 40 configured to store the plurality of battery cells 10. The battery module 1 may additionally include other elements not illustrated in the drawing. The battery cell 10 may be formed in a pouch shape, a prismatic shape, a cylindrical shape, and the like. The case 40 may be formed of a front portion 40a, a rear portion 40b, a lower portion 40c, and an upper portion 40d, but is not limited thereto. The shape of the case 40 and configurations included in the battery module 1 may vary depending on the types of battery cells 10.

The circuit board 30 included in the battery module 1 may include the flexible die-cut circuit board 100 according to an embodiment. The flexible die-cut circuit board 100 may be connected to various electronic components, including sensors such as temperature sensors, current sensors, and voltage sensors, fuses, battery management system (BMS) chips, and connectors. The flexible die-cut circuit board 100 may be used for the battery module 1 or a battery pack including a plurality of battery modules 1.

The flexible die-cut circuit board 100, according to an embodiment, may include: a substrate 110 made of a flexible material, the substrate 110 having a first surface 110a and a second surface 110b opposite to the first surface 110a; at least one trace 121 formed on the first surface 110a of the substrate 110; a pattern fuse 122 formed as a portion of the trace 121, the pattern fuse having a smaller thickness than other portions of the trace 121 and being configured to break when excessive current flows; and a protective layer 130 configured to cover the trace 121 and the pattern fuse 122. In this case, the pattern fuse 122 may be formed in a pattern having a curved shape in a direction perpendicular to the first surface 110a of the substrate 110. A layer where the trace 121 and the pattern fuse 122 are positioned may be referred to as a circuit layer 120. The circuit layer 120 may include at least one trace 121 and pattern fuse 122, and may further include an adhesive 123. The adhesive 123 may bond the substrate 110, the trace 121, and the protective layer 130.

The substrate 110 may be made of a flexible material. The trace 121 formed on the substrate 110 is formed of a thin metal film 200, and the protective layer 130 is also made of a flexible material. Accordingly, the flexible die-cut circuit board 100 is bendable. The substrate 110 may have the first surface 110a and the second surface 110b opposite to the first surface 110a. Electronic components, including sensors, semiconductor chips, fuses, and connectors, may be mounted on the substrate 110. Electronic components mounted on the substrate 110 may be connected to the trace 121.

The trace 121 may be formed of an electrically conductive metal film 200. The metal film 200 may be formed in the form of a thin film having a small thickness. The metal film 200 may be formed of copper (Cu), aluminum (Al), and other electrically conductive metals or alloys. The trace 121 may be formed on the first surface 110a or the second surface 110b of the substrate 110. The trace 121 formed on the first surface 110a of the substrate 110 and the trace 121 formed on the second surface 110b of the substrate 110 may be connected through a via hole penetrating the substrate 110. The trace 121 is formed on the substrate 110 and thus may serve as a circuit line connecting electronic components.

The trace 121 may be formed by performing die-cutting. Die-cutting is a method of cutting out a portion of the metal film 200 by pressing the metal film 200 using dies 300. Such dies 300 used for die-cutting may include those in a roller type, a press type, and the like. Due to technical limitations in die-cutting, it is difficult to form the width 121w of the trace 121 smaller than the predetermined limit. Such a difficulty is attributable to factors including precision in manufacturing the dies 300 used for die-cutting, tolerance generated in the process of moving the dies 300, and other causes. For example, when forming the trace 121 by performing die-cutting, it may be difficult to form the width 121w of the trace 121 smaller than 0.3 mm.

To use a portion of the trace 121 as a fuse, the width of this portion is required to be formed within a range of about 0.15 mm to 0.17 mm, but processing of the metal film 200 into such a width may be difficult to achieve by performing die-cutting. Accordingly, the pattern fuse 122 having a form in which the width 122w thereof is reduced may be difficult to manufacture. However, in an embodiment, a portion of the trace 121, the thickness 121t of which is formed to be small, may serve as the pattern fuse 122.

The pattern fuse 122 is a portion of the trace 121. The flexible die-cut circuit board 100 may include a plurality of traces 121, and the pattern fuse 122 may be formed only in some portions of the plurality of traces 121. The pattern fuse 122 may be formed in the trace 121 configured to perform sensing of voltage, current, and the like.

The pattern fuse 122 is a portion of the trace 121, the thickness 121t of which is formed to be small. The pattern fuse 122 may break when high current flows, thus blocking current flow. Therefore, the pattern fuse 122 may perform the same function as a fuse component. The flexible die-cut circuit board 100, according to an embodiment, may not involve the use of a chip-shaped fuse because the pattern fuse 122 is formed in the trace 121. Thus, chip fuse-related costs may be reduced.

The pattern fuse 122 may include a pattern in which the length of the portion, the thickness of which is formed to be small, is increased. This pattern may include at least one curve CV formed in the direction perpendicular to the first surface 110a of the substrate 110. In other words, the pattern fuse 122 may be formed in a serpentine shape in the direction perpendicular to the first surface 110a of the substrate 110. Alternatively, the pattern fuse 122 may be formed in a pattern in which a convex portion CV1 and a concave portion CV2 are formed repeatedly in the direction perpendicular to the first surface 110a of the substrate 110. The direction perpendicular to the first surface 110a of the substrate 110 is the same as the direction of the thickness 121t of the trace 121. Thus, the pattern of the pattern fuse 122 may also be described as having a serpentine shape in the direction of the thickness 121t of the trace 121. Because this pattern (the curve CV, the serpentine, the convex portion CV1, and the concave portion CV2) may increase the length through which the current flows relatively within the same area, the resistance of the pattern fuse 122 may be increased.

The protective layer 130 may be formed on the first surface 110a of the substrate 110 to cover the trace 121. The upper surface 130a of the protective layer 130 may be exposed to the outside. The lower surface 130b of the protective layer 130 may be in contact with the trace 121 and the pattern fuse 122. The protective layer 130 may be made of an electrically insulating material. The trace 121 and the pattern fuse 122 may be covered by the protective layer 130 and insulated from the outside. The protective layer 130 may be made of a flexible material. The substrate 110 and the protective layer 130 may also be formed of multiple layers.

Referring to FIGS. 2 and 3, the trace 121 and the pattern fuse 122 may have the same width 121w, 122w in at least one portion. The width 121w of at least one portion of the trace 121 and the width 122w of at least one portion of the pattern fuse 122 may be the same. As die-cutting is performed, a portion where the width 122w of the pattern fuse 122 and the width 121w of the trace 121 are the same may be formed.

Even when the width 122w of the pattern fuse 122 is the same as the width 121w of the trace 121, the thickness 122t of the pattern fuse 122 is smaller than the thickness 121t of the trace 121. For this reason, the cross-sectional area of the pattern fuse 122 may be smaller than that of the trace 121. Therefore, the pattern fuse 122 has relatively high resistance and may break due to heat generation when high current flows.

If necessary, the width 122w of the pattern fuse 122 may be formed smaller than the width 121w of the trace 121. Such a deformation may be achieved by designing the spacing between blades BL configured to cut the trace 121 and blades BL configured to cut the pattern fuse 122 to be different. When the width 122w and thickness 122t of the pattern fuse 122 are smaller than the width 121w and thickness 121t of the trace 121, the pattern fuse 122 is more likely to break when excessive current flows.

The width 122w, 121w and thickness 122t, 121t of the pattern fuse 122 and the trace 121 may be designed in consideration of the magnitudes of the steady current flowing through the trace 121 and the expected fault current (greater than the steady current).

Referring to FIG. 3, the convex portion CV1 and the concave portion CV2 of the pattern fuse 122 may be positioned within the thickness 121t of the trace 121. When the highest point of the convex portion CV1 and the lowest point of the concave portion CV2 are positioned within the thickness 121t of the trace 121, the substrate 110 and the protective layer 130 may not be separately processed. In addition, the thickness of the substrate 110 and the protective layer 130 in the portions corresponding to where the pattern fuse 122 is positioned may be the same as those in other portions, so that structural weakness may be avoided.

When the convex portion CV1 of the pattern fuse 122 is formed higher than the trace 121, the lower surface 130b of the protective layer 130 needs to be formed concavely. In addition, when the concave portion CV2 is formed lower than the first surface 110a of the substrate 110, the first surface 110a of the substrate 110 needs to be formed concavely. However, the process of forming portions of the protective layer 130 and the substrate 110 concavely is complicated, which may result in structural weakness in these portions.

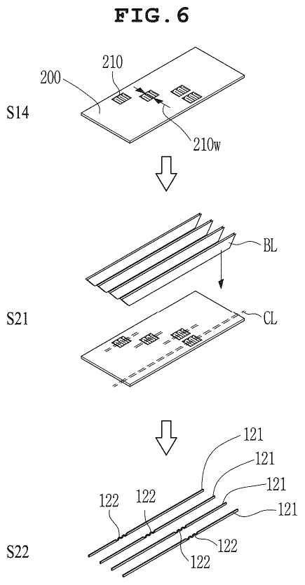

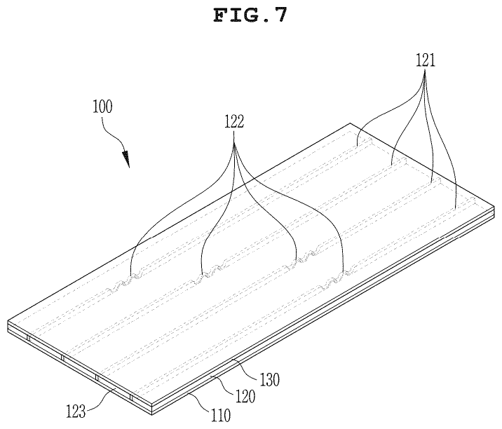

FIG. 4 is a flowchart illustrating each step constituting a method of manufacturing the flexible die-cut circuit board 100 according to an embodiment of the present disclosure. FIGS. 5, 6, and 7 are views illustrating each step constituting the method of manufacturing the flexible die-cut circuit board 100 according to an embodiment of the present disclosure.

The method of manufacturing the flexible die-cut circuit board 100, according to an embodiment, may include the following steps: S10 of pressing a metal film 200 using press dies 300 at a region where a pattern fuse 122 is to be formed in the metal film 200; S20 of forming a trace 121 and the pattern fuse 122 by performing die-cutting on the metal film 200 so that the pressed region 210 of the metal film 200 is included in the trace 121; and S30 of manufacturing a circuit board 30 by aligning the trace 121 and the pattern fuse 122 on a first surface 110a of a substrate 110 made of a flexible material and then forming a protective layer 130 configured to cover the trace 121 and the pattern fuse 122 on the substrate 110, wherein the pattern fuse 122 may be formed in a pattern having a curved shape in a direction perpendicular to the first surface 110a of the substrate 110.

Step S10 of pressing the metal film 200 involves using the dies 300 to press the region where the pattern fuse 122 is to be formed. Step S10 of pressing the metal film 200 may include the following steps: S11 of preparing the metal film 200; S12 of positioning the metal film 200 between the press dies 300; S13 of pressing the metal film 200 using the press dies 300; and S14 of removing the press dies 300.

See S11 of FIG. 5. Step S11 of preparing the metal film 200 may involve an operation of unwinding the metal film 200 wound on a roll (not shown) to transport the metal film 200 to a predetermined position. The metal film 200 may be supplied while being wound on the roll. The roll on which the metal film 200 is wound may be attached to an unwinder (not shown), thus allowing the metal film 200 to travel in one direction when the unwinder unwinds the roll. The metal film 200 may move to the predetermined position by a guide roller (not shown) and the like.

See S12 of FIG. 5. Step S12 of positioning the metal film 200 between the press dies 300 may involve an operation of aligning the press dies 300 to be positioned at the region where the pattern fuse 122 is to be formed in the metal film 200. The press dies 300 may include: a lower die 310 configured to support the lower surface of the metal film 200 at the region where the pattern fuse 122 is to be formed; and an upper die 320 configured to press the upper surface of the metal film 200 at the region where the pattern fuse 122 is to be formed. The metal film 200 may be positioned between the lower die 310 and the upper die 320. The lower die 310 and the upper die 320 may be aligned on a predetermined position to press the region where the pattern fuse 122 is to be formed.

See S13 of FIG. 5. Step S13 of pressing the metal film 200 using the press dies 300 involves moving one or both of the lower die 310 and the upper die 320 to press the metal film 200. When the lower die 310 and the upper die 320 press the metal film 200, the pressed metal film 200 may be deformed to have a small thickness.

A first curved pattern 330 having a convex shape on the upper surface 310a of the lower die 310, the upper surface 310a being in contact with the region where the pattern fuse 122 is to be formed, may be formed in the lower die 310, and a second curved pattern 340 having a convex shape on the lower surface 320b of the upper die 320, the lower surface 320b being in contact with the region where the pattern fuse 122 is to be formed, so as to correspond to a concave portion of the first curved pattern 330 may be formed in the upper die 320. A portion where the lower die 310 and the upper die 320 press the metal film 200 is where the curved pattern is formed. A plurality of first curved patterns 330 spaced from each other may be formed in the upper die 320, and a plurality of second curved patterns 340 spaced from each other may be formed in the lower die 310. The first curved pattern 330 and the second curved pattern 340 may be formed at positions facing each other.

The first curved pattern 330 and the second curved pattern 340 may press the metal film 200 while facing each other, thus forming the thickness of the pressed region 210 smaller than that of other regions not pressed, and forming a pattern having a curved shape in a direction perpendicular to the surface of the metal film 200.

While the lower die 310 and the upper die 320 press the metal film 200, the distance between the first curved pattern 330 and the second curved pattern 340 may correspond to the thickness 122t of the pattern fuse 122. In order for the convex portion CV1 and the concave portion CV2 of the pattern fuse 122 to be included within the thickness 121t of the trace 121, the height of the first curved pattern 330 and the height of the second curved pattern 340 may be determined to be smaller than the thickness 121t of the trace 121.

See S14 of FIG. 5. Step S14 of removing the press dies 300 involves moving one or both of the lower die 310 and the upper die 320 to separate the press dies 300 from the metal film 200. When the press dies 300 are removed, the pressed region 210 of the metal film 200 has a thickness that becomes small in accordance with the first curved pattern 330 and the second curved pattern 340, and curved patterns (see CV1 and CV2 in FIG. 3) may be formed in the direction perpendicular to the surface of the metal film 200.

See S14 of FIG. 6. The width 210w of the pressed region 210, pressed by the first curved pattern 330 and the second curved pattern 340, may be larger than the width 122w of the pattern fuse 122. In other words, the width 330w of the first curved pattern 330 and the width 340w of the second curved pattern 340 may be determined to be larger than the width 121w of the trace 121. In the process of performing die-cutting, it may be difficult for a cutter to cut the boundary of the pressed region 210 precisely. Thus, the pattern fuse 122 may be formed by forming the width 210w of the pressed region 210 sufficiently large and cutting the inside of the pressed region 210 using the cutter.

See S21 of FIG. 6. Step S20 of forming the trace 121 and the pattern fuse 122 involves cutting the metal film 200 to a predetermined width using die-cutting. Die-cutting may use a press-type cutter in which a plurality of blades BL is formed to press and cut the metal film 200. Alternatively, die-cutting may use a roller-type cutter in which a plurality of blades BL is formed on the surface of a roller to press and cut the metal film 200 by the rotation of the roller.

Step S20 of forming the trace 121 and the pattern fuse 122 may involve performing die-cutting so that the trace 121 and the pattern fuse 122 have the same width 121w, 122w in at least one portion. The dotted line in FIG. 6 indicates a cutting line CL along which cutting is performed through die-cutting. The spacing between the cutting lines CL to form one trace 121 is the same as the spacing between the blades BL of the cutter, and may be the same as the width 121w of a portion of the trace 121. The trace 121 and the pattern fuse 122 are cut at once using one pair of blades BL, so the width 121w of the trace 121 and the width 122w of the pattern fuse 122 may be formed to be the same. The spacing between the blades BL at some region may be determined so that the width 121w of at least one portion of the trace 121 and the width 122w of at least one portion of the pattern fuse 122 are the same or different. When the spacing between one pair of blades BL at some region is different, the width 121w, 122w of the trace 121 and the pattern fuse 122, corresponding to some region and the remaining regions, may be formed differently.

See S22 of FIG. 6. When cutting the metal film 200 using die-cutting, the trace 121 in which the pattern fuse 122 is formed may be manufactured. By cutting one metal film 200, a plurality of traces 121 may be formed.

See FIG. 7. Step S30 of manufacturing the circuit board 30 involves aligning the trace 121 and the pattern fuse 122, manufactured by performing die-cutting, on the substrate 110 and then forming the protective layer 130 configured to cover the trace 121 and the pattern fuse 122.

The substrate 110 or the protective layer 130 may be formed of multiple layers. For example, the trace 121 in which the pattern fuse 122 is formed may be aligned on the substrate 110, followed by forming the protective layer 130. Then, the trace 121 in which the pattern fuse 122 is formed may be aligned on the protective layer 130, followed by additionally forming the protective layer 130. In other words, a multilayer structure in which the substrate 110, the trace 121, and the protective layer 130 are repeatedly arranged may be formed. Step S30 of manufacturing the circuit board 30 may involve additionally mounting a sensor connected to the trace 121, a connector, a via hole penetrating the substrate 110, a semiconductor chip, and the like.

The method of manufacturing the flexible die-cut circuit board 100, according to an embodiment described above, can manufacture the trace 121 in which the pattern fuse 122 having a small thickness is formed. In addition, the flexible die-cut circuit board 100, including the pattern fuse 122 instead of a chip fuse, can be formed.

The present disclosure has been described in detail through specific embodiments. The above description is merely an example to which the principles of the present disclosure are applied, and other configurations may be further included without departing from the scope of the present disclosure.

What is claimed is:

1. A flexible die-cut circuit board comprising:
a substrate made of a flexible material, the substrate having a first surface and a second surface opposite to the first surface;
at least one trace formed on the first surface of the substrate;
a pattern fuse formed as a portion of the trace, the pattern fuse having a smaller thickness than other portions of the trace and being configured to break when excessive current flows; and
a protective layer configured to cover the trace and the pattern fuse.

2. The flexible die-cut circuit board of claim 1, wherein the pattern fuse is formed in a pattern having a curved shape in a direction perpendicular to the first surface of the substrate.

3. The flexible die-cut circuit board of claim 1, wherein the trace and the pattern fuse have the same width in at least one portion.

4. The flexible die-cut circuit board of claim 1, wherein the pattern fuse is formed in a pattern in which a convex portion and a concave portion are formed repeatedly in a direction perpendicular to the first surface of the substrate.

5. The flexible die-cut circuit board of claim 4, wherein the convex portion and the concave portion of the pattern fuse are positioned within a thickness of the trace.

6. The flexible die-cut circuit board of claim 1, wherein the trace is connected to electronic components mounted on the substrate.

7. The flexible die-cut circuit board of claim 1, wherein the trace is formed of a metal film in the form of a thin film.

8. The flexible die-cut circuit board of claim 1, further comprising:
at least one trace formed on the second surface of the substrate,
wherein the trace formed on the first surface of the substrate and the trace formed on the second surface of the substrate are connected through a via hole penetrating the substrate.

9. The flexible die-cut circuit board of claim 1, wherein the pattern fuse comprises a pattern in which the length of the portion having a reduced thickness is increased.

10. The flexible die-cut circuit board of claim 1, wherein width and thickness of the pattern fuse are smaller than width and thickness of the trace.

11. A method of manufacturing a flexible die-cut circuit board, the method comprising:
pressing a metal film using press dies at a region where a pattern fuse is to be formed in the metal film;
forming a trace and the pattern fuse by performing die-cutting on the metal film so that the pressed region of the metal film is included in the trace; and
manufacturing a circuit board by aligning the trace and the pattern fuse on a first surface of a substrate made of a flexible material and then forming a protective layer configured to cover the trace and the pattern fuse on the substrate.

12. The method of claim 11, wherein the pattern fuse is formed in a pattern having a curved shape in a direction perpendicular to the first surface of the substrate.

13. The method of claim 11, wherein the press dies comprise:
a lower die configured to support a lower surface of the metal film at the region where the pattern fuse is to be formed; and
an upper die configured to press an upper surface of the metal film at the region where the pattern fuse is to be formed.

14. The method of claim 13, wherein a first curved pattern having a convex shape on an upper surface of the lower die, the upper surface being in contact with the region where the pattern fuse is to be formed, is formed in the lower die, and
a second curved pattern having a convex shape on a lower surface of the upper die, the lower surface being in contact with the region where the pattern fuse is to be formed, so as to correspond to a concave portion of the first curved pattern is formed in the upper die.

15. The method of claim 11, wherein in the forming of the trace and the pattern fuse, the die-cutting is performed so that the trace and the pattern fuse have the same width in at least one portion.

16. The method of claim 11, wherein the pattern fuse is formed in a pattern in which a convex portion and a concave portion are formed repeatedly in a direction perpendicular to the first surface of the substrate.

17. The method of claim 16, wherein the convex portion and the concave portion of the pattern fuse are positioned within a thickness of the trace.
